(19) United States
(12) Patent Application Publication
(10) Pub. No.: US 2010/0073061 A1
(43) Pub. Date: Mar. 25, 2010

(54) INVERTER CIRCUIT

(75) Inventor: Takahisa TANABE, Saitama (JP)

Correspondence Address: DRINKER BIDDLE & REATH (DC), 1500 K STREET, N.W., SUITE 1100, WASHINGTON, DC, 20005-1209, US

(73) Assignee: PIONEER CORPORATION, TOKYO (JP)

(21) Appl. No.: 12/440,862

(22) PCT Filed: Sep. 4, 2007
(86) PCT No.: PCT/JP2007/067197

§ 371 Date: May 26, 2009

(30) Foreign Application Priority Data
Sep. 12, 2006 (JP) 2006-246430

(51) Int. Cl. H03K 3/00

(52) U.S. Cl. 327/291

(57) ABSTRACT

An inverter circuit using FETs which do not cause a fluctuation in gate threshold voltage Vth is provided. The inverter circuit has a load transistor and a driving transistor which is serially connected to the load transistor and supplies a load current to the load transistor in accordance with an input signal. The load transistor has at least two FETs which are connected in parallel and have controlled terminals. A driving part alternately turns on the FETs through the controlled terminals.

### TECHNICAL FIELD

The invention relates to an inverter circuit using field-effect transistors (FETs) and, more particularly, to an inverter circuit which suppresses a gate threshold voltage fluctuation caused by a gate stress of the FET.

### BACKGROUND ART

TFTs (Thin Film Transistors) which are used as elements for driving pixels of an organic EL display, a liquid crystal display, or the like, are a kind of FET and formed by amorphous silicon (a-Si), an organic semiconductor, or the like. With respect to the TFT elements, it has been known that when a predetermined voltage is continuously applied to a gate, it becomes a stress and fluctuation of the gate threshold voltage Vth occurs.

FIG. 1 shows drain current ID-gate voltage VGE characteristics before and after a negative voltage is/was applied in the case where the negative voltage is continuously applied between a gate and a source of an enhancement type p-channel TFT. In the diagram, P1 shows the initial ID-VGE characteristics of the p-channel TFT before the negative voltage is applied and P2 shows the ID-VGE characteristics after the negative voltage has been applied. That is, the diagram shows that when the gate stress of the negative voltage is continuously applied between the gate and the source of the p-channel TFT, the gate threshold voltage Vth fluctuates in the negative direction. When a gate stress of a positive voltage is continuously applied between the gate and the source, Vth fluctuates in the positive direction opposite to the above case.

It has also been known that the higher the voltage which is applied to the gate, the more a fluctuating speed of Vth rises and, further, Vth which was fluctuated by a gate bias is returned to the initial characteristics before the Vth fluctuation by a bias of a polarity opposite to that of the bias or by continuously applying 0V between the gate and the source.

Patent Literature 1 discloses a shift register for compensating the Vth fluctuation by applying a voltage according to the Vth fluctuation to a back gate.
Patent literature 1: Japanese Patent Kokai No. 2006-174294

### DISCLOSURE OF INVENTION

### Problem to be Solved by the Invention

A case where a TFT having the characteristics as mentioned above has been applied to an E/E type (enhancement type load/enhancement type driving) inverter circuit will now be considered. The E/E type inverter allows one of two transistors which are serially connected to function as a switch which is turned on/off in accordance with an input signal and allows the other to function as a load. Since the above type of inverter can be manufactured by processes of either one of an n-channel and a p-channel, there is such an advantage that it can be manufactured by simple processes by using a TFT formed by amorphous silicon or an organic semiconductor.

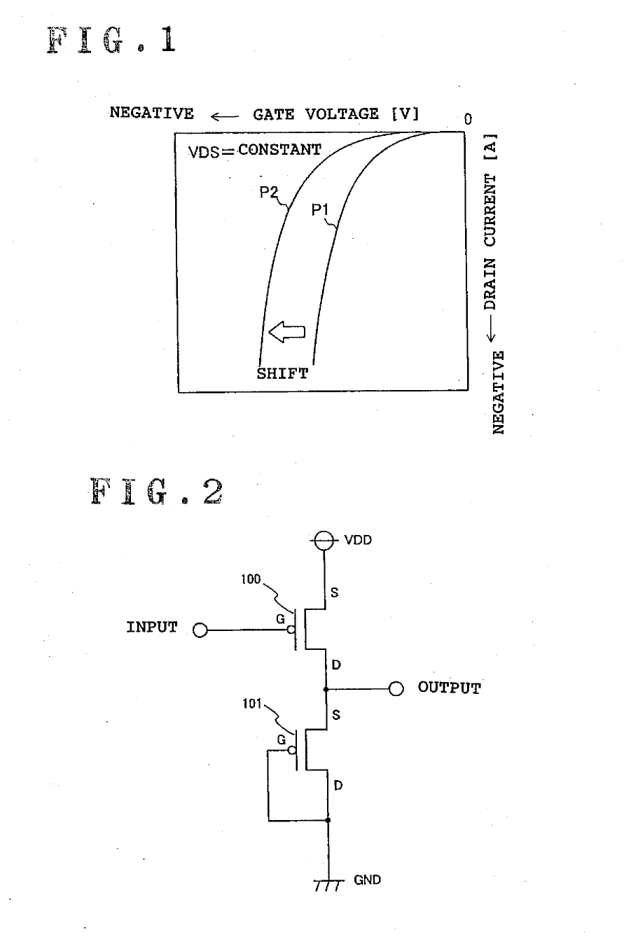

FIG. 2 is a diagram showing an example of a circuit construction of the E/E type inverter formed by p-channel FETs and the inverter is constituted by a driving TFT 100 and a load TFT 101. In the load TFT 101, a gate G and a drain D are fixed to a ground potential GND and a source S is connected to a drain D of the driving TFT 100 and functions as an output end of the inverter circuit. When a power voltage VDD is applied to a source S of the driving TFT 100, an input signal at a low level is applied to a gate G of the driving TFT 100 serving as an input end of the inverter circuit, the driving TFT 100 is turned on, and an output of the inverter circuit is set to the high level. That is, in this case, the power voltage VDD is divided at the output end at a voltage dividing ratio according to an ON resistance ratio of the driving TFT 100 and the load TFT 101 and the divided voltage is generated as an output voltage of the inverter circuit. When an input signal at a high level is applied to the gate G of the driving TFT 100, the driving TFT 100 is turned off and the output of the inverter circuit is set to the low level. In this case, however, the output voltage is not equal to 0V but a voltage which is higher than the ground potential GND by the gate threshold voltage Vth of the load TFT 101 is generated from the output end.

Since the gate G of the load TFT 101 is now fixed to the ground potential GND, the output voltage which is set to the high level or the low level according to the output of the inverter circuit is intermittently applied between the gate G and the source S of the load TFT 101. Even when the output voltage of either the high level or the low level has been applied, the voltage between the gate and the source of the load TFT 101 becomes negative, becomes a gate stress, and causes a fluctuation in gate threshold voltage Vth of the load TFT 101. In this case, in a manner similar to the case where the negative voltage has been applied to the gate G, Vth fluctuates in such a direction as to increase its absolute value.

When the Vth fluctuation progresses, the load characteristics of the load TFT 101 change largely, in the extreme case, a state between the source S and the drain D of the load TFT 101 enters an almost non-conductive state and there is a risk that the TFT does not function at all as a load.

The invention is made in consideration of the foregoing problems and it is an object of the invention to provide an inverter circuit using TFTs which do not cause a fluctuation in gate threshold voltage.

### Means for Solving the Problem

According to the invention, there is provided an inverter circuit comprising a load transistor and a driving transistor which is serially connected to the load transistor and supplies a load current to the load transistor in accordance with an input signal, wherein the load transistor has: at least two FETs which are connected in parallel and have controlled terminals; and a driving part for alternately turning on the FETs through the controlled terminals.

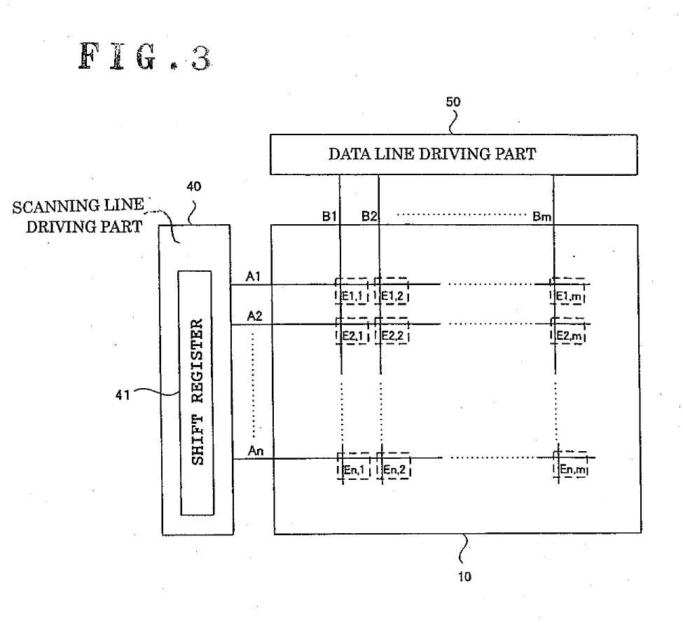

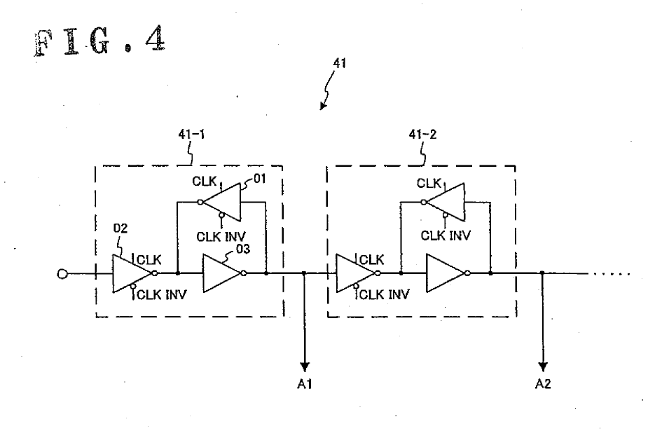

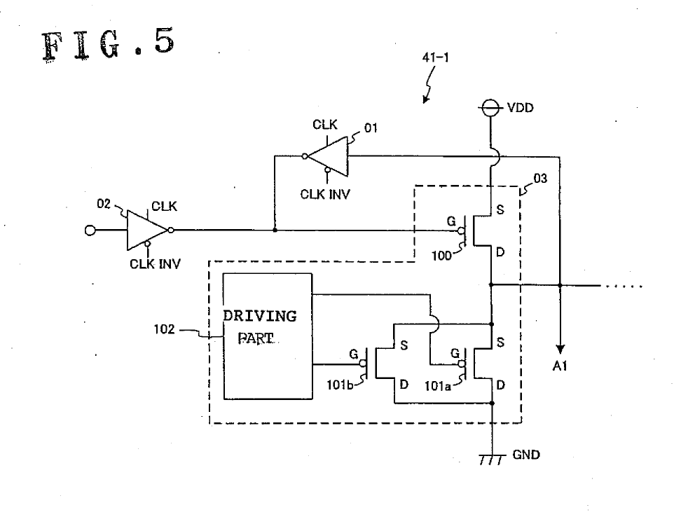

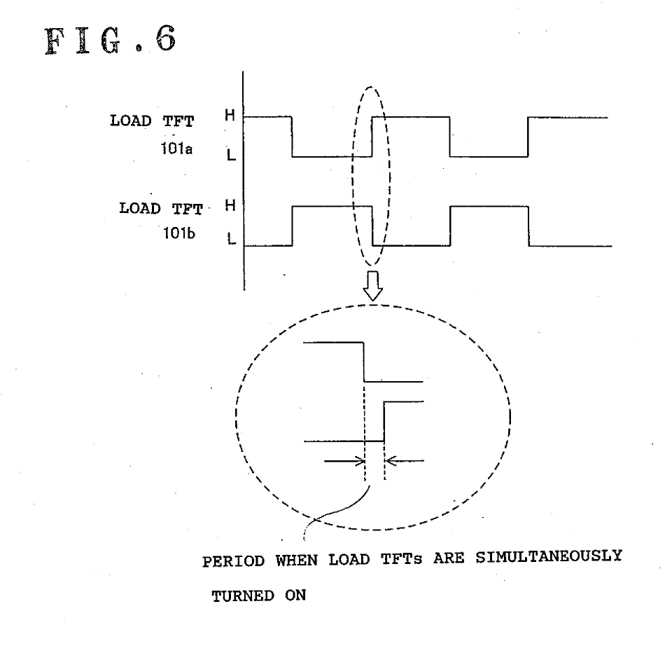

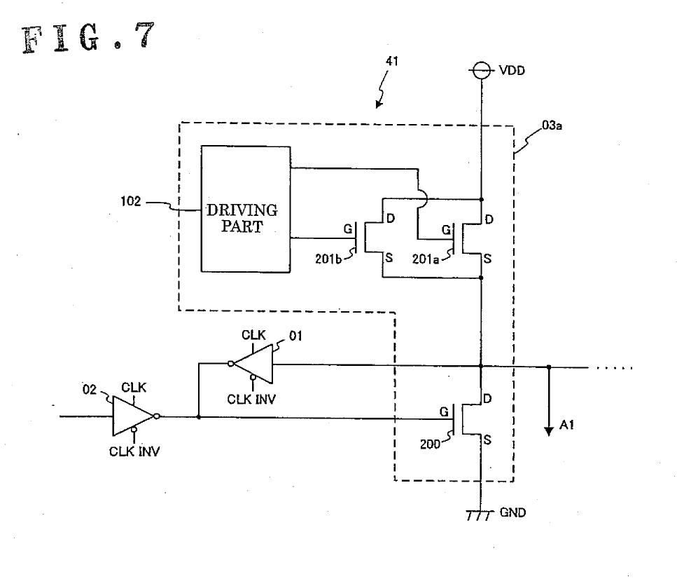

### BRIEF DESCRIPTION OF DRAWINGS

[FIG. 1] Diagram showing drain current-gate voltage characteristics before and after a negative voltage is/was applied in the case where the negative voltage is continuously applied between a gate and a source of an enhancement type p-channel TFT.

[FIG. 2] Circuit diagram showing an example of an inverter circuit in the related art.

[FIG. 3] Schematic constructional diagram of an EL display apparatus having an inverter circuit according to an embodiment of the invention.

[FIG. 4] Circuit block diagram of a shift register including the inverter circuit according to the embodiment of the invention.

[FIG. 5] Circuit block diagram of the shift register including the inverter circuit according to the embodiment of the invention.

[FIG. 6] Timing chart for driving pulse signals which are supplied to the inverter circuit according to the embodiment of the invention.

[FIG. 7] Circuit block diagram of a shift register including an inverter circuit according to another embodiment of the invention.

### MODE FOR CARRYING OUT THE INVENTION

An embodiment of the invention will be described hereinbelow with reference to the drawings. In the following diagrams, substantially the same or equivalent component elements and portions are designated by the same reference numerals.

In the embodiment, a case where an inverter circuit according to the invention is applied to a shift register of a scanning line driving circuit in a display apparatus of a matrix driving system will be described as an example.

FIG. 3 is a diagram showing a schematic construction of an EL display apparatus of the matrix driving system. As shown in FIG. 3, the EL display apparatus is constituted by: a display panel 10; and a scanning line driving part 40 and a data line driving part 50 for driving the display panel 10 in accordance with a video signal. Scanning lines Aₗ to Aₙ serving as n horizontal scanning lines and m data lines B₁ to Bₘ arranged so as to cross the scanning lines, respectively, are formed on the display panel 10. Light emitting elements (not sown) such as organic EL elements serving as pixels and pixel driving circuits E_{1,1} to E_{n,m} for driving the light emitting elements are formed in crossing portions of the scanning lines A₁ to Aₙ and the data lines B₁ to Bₘ on the display panel 10, respectively. The pixel driving circuits E_{1,1} to E_{n,m} are constituted by TFTs which are formed on a glass substrate of the display panel 10 and each of which is made of amorphous silicon or an organic semiconductor.

By sequentially supplying scanning pulse signals to the scanning lines A₁ to Aₙ, the scanning line driving part 40 turns on the TFTs (not shown) constructing the pixel driving circuits connected to the scanning lines and sets the TFTs into targets to which pixel data is written. The data line driving part 50 generates a pixel data pulse signal according to the input video signal corresponding to each horizontal scanning line synchronously with timing for supplying the scanning pulse signal and supplies the pixel data pulse signal to each of the data lines B₁ to Bₘ. Each of the pixel data pulse signals has a pulse voltage according to a luminance level shown by each input video signal. Each of the TFTs (not shown) in the pixel driving circuits which have been turned on in response to the scanning pulse signals supplies a light emission driving current according to the pixel data pulse signal supplied through the data line to the light emitting element (not shown). The light emitting element emits light at luminance according to the light emission driving current. The pixel data pulse signal is held in a capacitor (not shown). Even after the stop of the supply of the pixel data pulse signal, the light emission driving current is continued to be supplied to the light emitting element. One frame (one picture plane) is formed by the operation.

The scanning line driving part 40 has a shift register 41 for sequentially supplying the scanning pulse signals to the scanning lines A₁ to Aₙ. In a manner similar to the pixel driving circuits E_{1,1} to E_{n,m}mentioned above, the shift register 41 is also constituted by TFTs which are formed on the glass substrate of the display panel 10 and each of which is made of amorphous silicon or an organic semiconductor. FIG. 4 is a diagram showing an example of a construction of the shift register 41 constructing the scanning line driving part 40. In the shift register 41, n register circuits 41-1, 41-2, . . . corresponding to the n scanning lines are serially connected. An output pulse which is generated from each of the register circuits 41-1, 41-2, . . . is supplied to the register circuit of the next stage and those output pulses are also supplied to the corresponding scanning lines A₁, A₂, . . . . Each register circuit is constituted by clocked inverters 01 and 02 and an inverter 03. A clock signal CLK as a sync signal of the shifting operation and an inversion clock signal CLKINV obtained by inverting the clock signal CLK are supplied to the clocked inverters 01 and 02 while being alternately switched according to the odd-number designated stages and the even-number designated stages of the register circuits. Each of the register circuits 41-1, 41-2, . . . is a state storing circuit of 1 bit and switches the writing/holding operations in accordance with the supplied clock signal and inversion clock signal. At this time, since the clock pulse CLK and the inversion clock pulse CLKINV are supplied while being alternately switched according to the odd-number designated stages and the even-number designated stages, the writing/holding operations are alternately executed according to the odd-number designated stages and the even-number designated stages. By the operations, the shift register 41 sequentially shifts the scanning pulse signals supplied to the register circuit 41-1 at the first stage and sequentially supplies the scanning pulse signals to the scanning lines.

The inverter 03 constructing the shift register 41 can be constituted by the E/E type (enhancement type load/enhancement type driving) inverter circuit as mentioned above. FIG. 5 is a block diagram of a register circuit in which the inverter 03 in the shift register 41 shown in FIG. 4 is constituted by the inverter circuit according to the invention. The inverter circuit 03 is constituted by: the driving TFT 100; load TFTs 101a and 101b connected in parallel; and a driving part 102 for supplying driving pulse signals to drive the load TFTs 101a and 101b. All TFTs constructing the inverter circuit 03 are enhancement type p-channel FETs. That is, the load TFTs 101a and 101b and the driving TFT 100 are formed by manufacturing processes of the p-channel FETs.

Output signals from the clocked inverters 01 and 02 are supplied as input signals of the inverter circuit 03 to the gate G of the driving TFT 100 serving as an input end of the inverter circuit 03.

The power voltage VDD is applied to the source S of the driving TFT 100 and the drain D is connected to the load TFTs 101a and 101b. The driving TFT 100 is turned on/off in accordance with the input signal supplied through the gate G. The driving TFT 100 extracts a load current from a power source and supplies it to the load TFTs 101a and 101b at the ON operation and stops the supply of the load current at the OFF operation, thereby switching an output voltage of the inverter circuit 03.

The load TFTs 101a and 101b serving as loads of the inverter circuit 03 are connected in parallel, their drains D are fixed to the ground potential, and their sources S are connected to the drain D of the driving TFT 100. Its connecting point serves as an output end of the inverter circuit 03. An output voltage which is generated from the output end is supplied to the register circuit at the next stage and is also supplied as a scanning pulse signal to the corresponding scanning line. Gates G as controlled terminals of the load TFTs 101a and 101b are connected to the driving part 102.

The driving part 102 supplies the driving pulse signals through the gates G of the load TFTs 101a and 101b, thereby driving and controlling the load TFTs 101a and 101b. That is, in the inverter circuit 03 of the invention, gate potentials of the load TFTs are not fixed to a certain predetermined state but are changed in accordance with the driving pulse signals supplied from the driving part 102. Further, the load TFTs are turned on/off by applying the driving pulse signals.

Since the load TFTs 101a and 101b are connected in parallel here, when either one of them is ON, the load current flows in the TFT in the ON state, so that the function as a load is assured. By driving and controlling the load TFTs 101a and 101b as will be explained hereinafter, therefore, the driving part 102 eliminates the gate stresses to the load TFTs 101a and 101b and suppresses the Vth fluctuation.

That is, in the inverter circuit in the related art, as mentioned above, the gate potential of the load TFT is fixed, the output voltage at the high level and the low level is intermittently applied between the gate G and the source S of the load TFT in accordance with the output of the inverter circuit, and it becomes the gate stress and causes the fluctuation in gate threshold Vth. According to the invention, on the other hand, by alternately positively and negatively biasing the voltage across the gate G and the source S of each load TFT, while assuring the function as a load, the gate stress is eliminated and the occurrence of the Vth fluctuation is prevented.

FIG. 6 shows an example of a timing chart for the driving pulse signal which is supplied to each of the gates G of the load TFTs 101a and 101b by the driving part 102. As shown in FIG. 6, the driving part 102 alternately supplies the high-level driving pulse signal (OFF signal) and the low-level driving pulse signal (ON signal) to the load TFTs 101a and 101b at a predetermined period of a duty ratio of 50%. That is, the driving part 102 supplies the driving pulse signals having the two signal levels to the load TFTs so as to have the opposite phases. The voltage of the high-level driving pulse signal is set to, for example, a value equal to the high-level output voltage of the inverter circuit 03. The voltage of the low-level driving pulse signal is set to, for example, a ground potential (0V). When the high-level driving pulse signal is applied to the load TFT, the load TFT is turned off. When the low-level driving pulse signal is applied, the load TFT is turned on. Since the driving pulse signals of the high level and the low level are alternately supplied to the load TFTs as mentioned above, when the load TFT 101a is ON, the load TFT 101b is OFF, and when the load TFT 101a is OFF, the load TFT 101b is ON. In other words, since either one of the load TFTs is certainly ON, the function as a load is always assured.

It is preferable that upon switching of the high level/low level of the driving pulse signal, as shown in FIG. 6, a period of time for simultaneously supplying the low-level driving pulse signal to both of the load TFTs 101a and 101b is provided, thereby preventing the inverter operation from being obstructed. That is, by adjusting the driving timing as mentioned above, the high-level driving pulse signal is simultaneously supplied to both of the load TFTs, so that such a situation that both of the load TFTs are simultaneously turned off can be certainly prevented.

By making the gate voltage control of the load TFTs as mentioned above, a period of time during which the gate G of the load TFT is positively biased for the source S and a period of time during which it is negatively biased exist. That is, for a period of time during which the output voltage of the inverter is at the low level and the high-level driving pulse signal is supplied to the load TFT from the driving part 102, the gate G of the load TFT is positively biased, and for a period of time during which the output voltage of the inverter is at the high level and the low-level driving pulse signal is supplied to the load TFT from the driving part 102, the gate G of the load TFT is negatively biased. By setting the magnitudes of the positive bias and the negative bias to be equal and by setting the duty ratio of the driving pulse signals so that a length of the positive-bias period and that of the negative-bias period per unit time are almost equal, the average voltage between the gate G and the source S of the load TFT can be set to be almost zero. The gate stress is, thus, eliminated and the Vth fluctuation of the load TFT can be suppressed. In the embodiment, in order to set the average voltage between the gate G and the source S of the load TFT to be almost zero, the voltage of the high-level driving pulse signal which is applied to the gate G is set to the output voltage of the inverter, the voltage of the low-level driving pulse signal is set to the ground potential, and the duty ratio of the driving pulse signals is set to 50%. The invention, however, is not limited to the above example but it may be properly changed according to Vth fluctuation characteristics of the TFT.

Although each of the load TFT and the driving TFT is constituted by a p-channel FET in the embodiment, they may be constituted by n-channel FETs. FIG. 7 is a circuit block diagram in the case where the inverter circuit in the embodiment is constituted by n-channel FETs. As shown in the diagram, when the E/E type inverter circuit is constituted by the n-channel FETs, load TFTs 201a and 201b connected in parallel are connected to the power source side and a driving TFT 200 is connected to the GND side. Although a supplying method of the driving pulse signal which is supplied to each load TFT from the driving part 102 is substantially the same as that in the case of the p channel, it differs from the case of the p channel with respect to a point that the load TFT is turned on by the high-level driving pulse signal and is turned off by the low-level driving pulse signal. Also in this case, the gate stress of the load TFT is eliminated and the Vth fluctuation can be suppressed.

Although the driving part 102 supplies the driving pulse signal to each load TFT in the embodiment, when the voltages of the high level and the low level of the clock pulse CLK have been set to the voltages which can turn on/off the load TFTs, in place of the driving pulse signals, the existing clock pulse CLK and inversion clock pulse CLKINV may be supplied to the gates G of the load TFTs. The load TFTs can be, consequently, driven without individually providing the driving part 102 and the inverter circuit can be simply constructed.

Although the case where the inverter circuit is applied to the shift register of the scanning line driving part has been described as an example in the embodiment, the invention is not limited to it but can be applied to various circuits constituted by the TFTs.

Although the load TFT is constituted by connecting the two FETs in parallel and they are alternately turned on in the embodiment, three or more FETs may be mutually connected in parallel. In the case, it is sufficient to set the driving pulse signals so as to turn on the TFTs in predetermined order in such a manner that at least one of the load TFTs is turned on.

As will be understood from the above description, according to the inverter circuit of the invention, the load TFT is constituted by at least two TFTs connected in parallel, the driving pulse signal is supplied in such a manner that the period of time during which the voltage between the gate and the source of each load TFT is positively biased and the period of time during which it is negatively biased are almost equal, and control is made so that at least one of the load TFTs is turned on by the driving pulse signal. While each load TFT, therefore, assures the function as a load, the fluctuation in gate threshold voltage Vth can be suppressed.

1. An inverter circuit comprising:
at least two field-effect transistors (FETs) which are connected in parallel and have controlled terminals;
a driving transistor which is serially connected to said at least two field-effect transistors and supplies a load current to said at least two field-effect transistors in accordance with an input signal; and
a driving part for alternately turning on said at least two field-effect transistors through said controlled terminals.

2. An inverter circuit according to claim 1, wherein said driving part supplies driving pulse signals having two signal levels to said FETs so as to have opposite phases.

3. An inverter circuit according to claim 2, wherein said driving pulse signal positively biases or negatively biases a voltage between a gate and a source of said FET in accordance with its signal level.

4. An inverter circuit according to claim 2, wherein generating periods of the signal levels of said driving pulse signals are almost equal.

5. An inverter circuit according to claim 1, wherein said at least two field-effect transistors and said driving transistor are formed by a same process.

6. An inverter circuit according to claim 1, wherein said at least two field-effect transistors and said driving transistor are pchannel FETs.

7. An inverter circuit according to claim 1, wherein said at least two field-effect transistors and said driving transistor are n-channel FETs.

8. An inverter circuit according to claim 1, wherein each of said at least two field-effect transistors and said driving transistor is made of amorphous silicon.

9. An inverter circuit according to claim 1, wherein each of said at least two field-effect transistors and said driving transistor is made of an organic semiconductor.
